(19) United States
(12) Patent Application Publication
(10) Pub. No.: US 2021/0303042 A1
(43) Pub. Date: Sep. 30, 2021

(54) MOTHERBOARD ARRANGEMENT METHOD FOR IMPROVING COMPUTER PERFORMANCE AND MOTHERBOARD THEREOF

(71) Applicant: EDAC ELECTRONICS TECHNOLOGY (HANGZHOU) CO., LTD, HANGZHOU (CN)

(72) Inventor: Jinsong Shi, Hangzhou (CN)

(21) Appl. No.: 16/835,416

(22) Filed: Mar. 31, 2020

(51) Int. Cl. G06F 1/20; H05K 1/18; H05K 1/14

(52) U.S. Cl. CPC G06F 1/20; H01L 23/467; H05K 1/14; H05K 1/18

(57) ABSTRACT

In view of the existing problems affecting computer performance due to poor CPU cooling, this disclosure provides a motherboard arrangement method for improving the performance of the computer and a motherboard thereof, CPU being arranged on the back side of the circuit board, memory slots, expansion slots, peripheral interfaces and other components being arranged on the front side of the circuit board. The heat generated by CPU is directly transferred into a space between the back side of the motherboard and the corresponding side of the case through the cooling fan, the effective cooling and insulation space is formed in the case. It is easy for air circulation, to exhaust hot air outside the case by the power fan, and to make the cold air outside the case inside to improve the cooling efficiency greatly.

### TECHNICAL FIELD OF THE INVENTION

The disclosure relates to a computer motherboard arrangement method and a motherboard thereof, in particular, being conducive to heat dissipation so as to reduce the failure rate of the computer and improve the performance of the computer.

### BACKGROUND OF THE INVENTION

The stable operation of a computer as a whole depends mainly on the structure of a motherboard. The motherboard is equipped with a CPU, memory slot, expansion slot, Northbridge chip, and integrated circuits and other electronic components which play a variety of controls for the reliability of the computer operation. Because the operation of the computer mainly depends on the high-speed operation of the CPU, the CPU in high-speed operation often produces a large amount of heat, the surface temperature can reach 50-80 degree centigrade, and the inside of the CPU is as high as 80 degrees centigrade or even more than 100 degrees centigrade. However, the CPU operating temperature is about 50 degrees centigrade, overtemperature will seriously affect the stability and service life of the CPU, resulting in slow operation, system failure, and even the chip peripheral components burned or CPU fan burned. In order to dissipate the heat generated by the CPU, air cooling is the current common way in the art, usually fixed a heat sink with a fan on the CPU. According to the principle of heat convection, the CPU will transfer heat to the heat sink, and then heat sink transfers heat into the case. The CPU fan is used to accelerate convection, and finally the case is drained by the power supply fan. Early computers generated less heat when running, which could be taken away by the outwards exhaust from the CPU fan and the power fan. With the development of technology, CPU's clock speed and motherboard's bus frequency are getting higher and higher, and the computer produces more and more heat when running. Therefore, the CPU cooling becomes the key to ensure the good operation of the computer. At present, many solutions have been designed to solve this problem, however, most of them are to improve the CPU heat sink and fan cooling effect with the following the disadvantages: 1) With the CPU cooling time going on, the power fan cannot take away the hot air inside the case fully, so that the hot air is basically circulated in the case and the temperature inside the case will be higher and higher. The CPU heat sink and fan cannot work basically, resulting in poor CPU cooling effect. 2) With the development of technology, the heat increases with the CPU main frequency being higher and higher, so that heat dissipation issues have become a bottleneck to improve CPU speed. However, the components on the motherboard, especially slots and boards, become more and more so as not to be conducive to the circulation of air, resulting in poor CPU cooling effect. 3) As heat builds up in the case, it affects the stability of other components. 4) Because the air outside flows into the case, some dust will bring into the case. This dust will deposit on the components resulting in affecting the stability and service life of the components. There are some other ways to dissipate heat, such as, “COMPUTER CASE COOLING METHOD AND DEVICE THEREOF” (CN1395154A, 20030205) discloses an active ventilation dissipating heat method and device for the back of the motherboard and its welding points, however, the application's technical solution improves heat dissipation while bringing more dust deposition problems, which is not conducive to the stable operation of the computer.

### SUMMARY OF THE INVENTION

The main purpose of the disclosure is to overcome the deficiency of computer cooling technology in the art, break the rigid thinking set, provide a new computer motherboard arrangement method, so as to greatly reduce the heat accumulation in the case and dust deposits generated by cooling wind, thereby improving the overall performance of the computer. At the same time, a new computer motherboard is provided.

The purpose of the disclosure can be achieved by means of the following technical solution: a motherboard arrangement method to improve the stability of the computer is to arrange the CPU at the back side of the main circuit board opposite to the side where the memory slot, expansion slot, peripheral interface and other components arranged. An expansion of the ventilation cooling channel for CPU is provided with the back of the main circuit board and the side wall of the case. A ventilation hole is provided on the side wall of the case near the CPU.

A motherboard to improve computer stability includes a main circuit board 2, a CPU 1, a memory slot 3, an expansion slot 4, and a peripheral interface 5; the memory slot 3, expansion slot 4, and peripheral interface 5 are located on the front side of the main circuit board 2, the CPU is located on the back side of the main circuit board 2. An expansion of the ventilation cooling channel for CPU is provided with the back of the main circuit board and the side wall of the case. A ventilation hole is provided on the side wall of the case near the CPU.

The beneficial effect of the disclosure is: the current computer motherboard is arranged the CPU, memory slot, expansion slot, peripheral interface and other components on the front side of the main circuit board, which has become a mind-set. The technical solution of the disclosure is to arrange the CPU on the back side of the main circuit board opposite to the side where the memory slot, expansion slot, peripheral interface and other components arranged. The arrangement has three effects: 1) the heat emitted by the CPU is directly brought into a space between the back side of the main circuit board and the corresponding side of the main case by the dissipation fan. Because there is not any other component in the space, it is easy for air circulation, to exhaust hot air outside the case by the power fan, and to make the cold air outside the case inside to improve the cooling efficiency greatly, thereby greatly reducing the internal temperature of the computer case, reducing the computer failure rate, and directly or indirectly reducing the cost of the whole machine and maintenance costs. 2) Because the CPU is located on the back side of the main circuit board, the impact on other components brought from the dust generated by the CPU cooling wind is greatly reduced by the isolation of the main circuit board, 3) the available area of the front side of the main circuit board in the computer case is greatly expanded, which facilitates the arrangement of memory slots, expansion slots, peripheral interfaces and other components, adapts to future trends of the motherboard with more and more components, and be able to adapt to the future trend.

The characteristics and advantages of the invention will be detailed by the embodiment combined with the drawings.

### BRIEF DESCRIPTION OF THE DRAWINGS

FIG. 1 is the common arrangement of computer motherboard in the art;

FIG. 2 is a motherboard technical solution of the present disclosure;

FIG. 3 is another motherboard technical solution of the present disclosure.

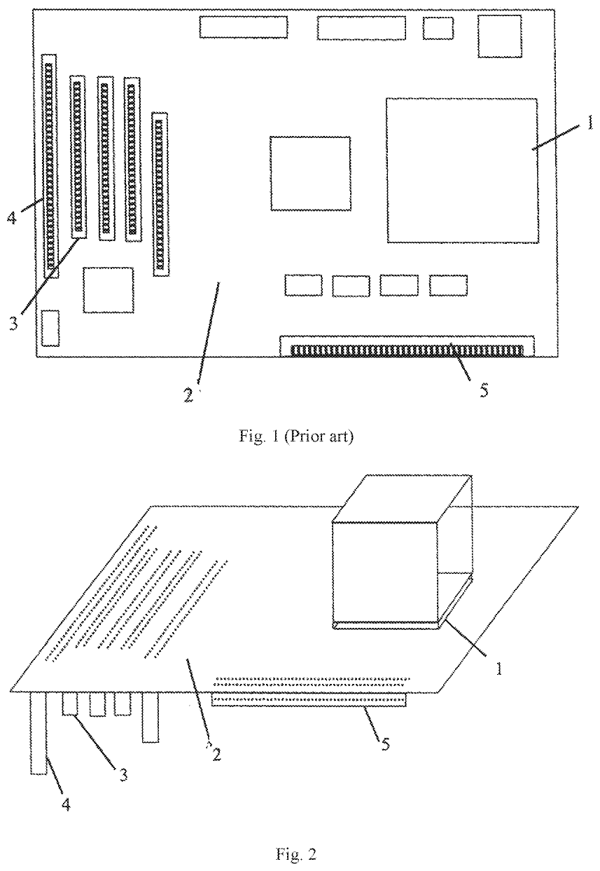

### DETAILED DESCRIPTION OF THE EMBODIMENTS

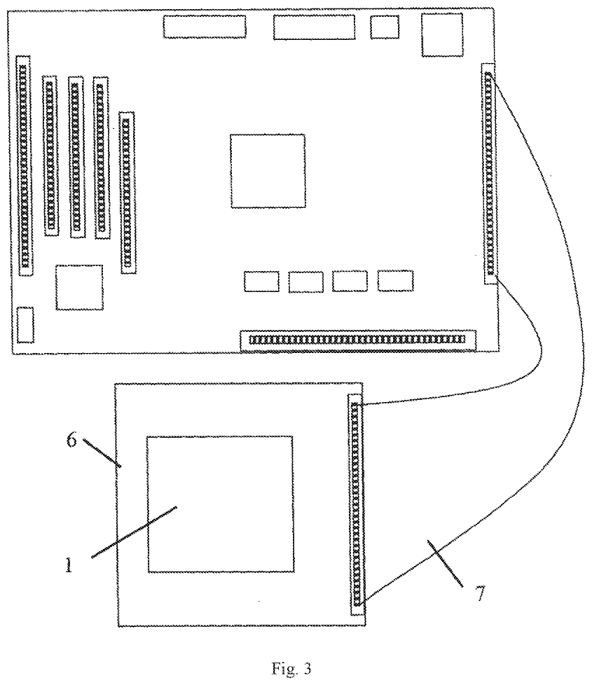

As shown in FIG. 2, an embodiment of the present disclosure is provided. The computer motherboard includes CPU 1 and its carrier socket, a memory slot 3, an expansion slot 4, and a peripheral interface 5, etc., wherein, CPU 1 and its carrier socket are located on the back side of the main circuit board, the memory slot 3, expansion slot 4, and peripheral interface 5, etc. are located on the front side of the main circuit board, CPU carrier socket is connected to the memory slot 3, expansion slot 4, peripheral interface 5 and other components via the printed circuits on the surface or interior of the main circuit board, and CPU 1 is plugged into the CPU carrier socket.

As shown in FIG. 3, another embodiment of the present disclosure is provided. The difference from the above embodiment is that the computer motherboard further includes an attached circuit board 6 and an adapter card 7, CPU 1 and its carrier socket are located on the attached circuit board 6, the attached circuit board 6 is fixed at the wall of case where the back side of the main circuit board is located, the memory slot 3, expansion slot 4, and peripheral interface 5 are located on the front side of the main circuit board, and the attached circuit board 6 is connected to the main circuit board via the adapter card 7. Because the CPU is provided with heat sinks and fans, and with heavy weight, this embodiment can make the motherboard weight balance. When using the motherboard, the interior of the computer case should be adjusted appropriately, including the height of the bracket fixing the main circuit board of the computer should be increased, so that there is sufficient space for the corresponding CPU and the heat exchanger fan thereon to be installed in place. At the same time, the corresponding ventilation hole is drilled on the case wall near the CPU fan. Because a large space exists above the motherboard, so the height increase of computer main circuit board bracket will not affect the other components in the computer, it is also easy to achieve in the circuit technology without increasing costs, and the product competitiveness is enhanced.

What is claimed is:

1. A motherboard arrangement method for improving the stability of the computer comprising: arranging a CPU on the back side of the main circuit board opposite to the side where a memory slot, expansion slot, peripheral interface and other components arranged, forming an expansion of the ventilation cooling channel for CPU with the back side of the main circuit board and the side wall of the case, arranged a ventilation hole on the side wall of the case near the CPU.

2. The motherboard arrangement method according to the claim 1, wherein the CPU is directly welded or plugged via the carrier socket of CPU onto the back side of the main circuit board.

3. The motherboard arrangement method according to the claim 1, wherein the CPU is directly welded or plugged onto an attached circuit board via the carrier socket of CPU, the attached circuit board is connected with the main circuit board via an adapter card, and the adapter card is provided on the back side of the main circuit board.

4. The motherboard arrangement method according to the claim 3, wherein the attached circuit board is fixed to the case wall towards the back side of the motherboard.

5. A motherboard for improving computer stability comprising a main circuit board (2), a CPU (1), a memory slot (3), an expansion slot (4), and a peripheral interface (5), wherein the memory slot (3), expansion slot (4), and peripheral interface (5) are located on the front side of the main circuit board (2), the CPU is located on the back side of the main circuit board (2), an expansion of ventilation cooling channel for CPU is consisted of the back side of the main circuit board and the side wall of the case, and a ventilation hole is provided on the side wall of the case near the CPU.

6. The motherboard according to the claim 5, wherein the CPU is directly welded or plugged via the carrier socket of CPU onto the back side of the main circuit board (2).

7. The motherboard according to the claim 5, further comprising an attached circuit board (6) and an adapter card (7), wherein the CPU is located on the attached circuit board (6), the attached circuit board (6) is fixed on the case wall towards the back side of the main circuit board (2), the attached circuit board (6) is connected with the main circuit board (2) through the adapter card (7).
